(19) United States
(12) Patent Application Publication
(10) Pub. No.: US 2011/0018524 A1
(43) Pub. Date: Jan. 27, 2011

(54) System and Method for Nondestructive Detection of Electrical Sensors and Cables

(76) Inventor: Gary F. Fitzsimmons, Simpsonville, SC (US)

Correspondence Address: NEXSEN PRUET, LLC, P.O. BOX 10648, GREENVILLE, SC, 29603, US

(21) Appl. No.: 12/508,973

(22) Filed: Jul. 24, 2009

(51) Int. Cl. G01R 1/06

(52) U.S. Cl. 324/149

(57) ABSTRACT

A system and method for noninvasive and nondestructive identification of electrical sensors and cables in multi-channel data acquisition (DAQ) systems includes a probe comprising a slotted, wound toroid in series with a blocking capacitor connected to, and powered by, a frequency generator. The frequency generator is tuned to output a test signal set at a multiple harmonic frequency of the DAQ system carrier or scanner frequency. This test signal is then induced into the electrical sensor cable by placing the cable into the toroid slot, whereby the sensor cable provides a path for the test signal to combine with the DAQ system operating frequency so that the resultant combined signal is displayed on the DAQ system monitor. In this way the specific sensor and cable may be identified to avoid the normal procedure of disconnecting or shorting the sensor cables.

### FIELD OF THE INVENTION

The present invention generally relates to a system and method for identifying sensors and cables in moderate to large multi-channel data acquisition (DAQ) systems. More specifically, the system comprises a slotted, wound toroid that is powered by a frequency generator (FG). In a typical application, a sensor cable is placed in the toroid slot and the FG is set to a multiple harmonic frequency of the DAQ system carrier or scanning frequency (sometimes referred to as the operating frequency), plus or minus a small amount. The multiple harmonic frequency from the toroid then mixes with the DAQ operating signal to form a resultant or combined signal that is easily readable in the DAQ monitoring system display or other monitoring system display, such as an attached oscilloscope. The combined signal is easily induced and emphasized for identification on the DAQ system by varying FG frequency, amplitude, and waveform profile.

### BACKGROUND OF THE INVENTION

Typically cables and sensors are identified in large, multi-channel DAQ systems by opening or short circuiting the sensor or its connector. This often results in damage to the sensor or creates unreliable connections, which is of particular importance in one of the most common applications of large DAQ systems—aircraft avionics.

Strain gages, for example, are very delicate and small. After installation and moisture-proofing, strain gages must operate by measuring multiple mega ohms to ground to provide reliable strain data. The normal identification procedure is, therefore, to short the strain gage while the system operator views the DAQ monitor to confirm the shorted condition. The intrusive nature of this shorting process generally results in damage to more than two percent of the strain gages, which requires replacement of the sensor and additional down time. The shorting process may compromise the moisture-proof coating over the strain gages and connecting wires. Fatigue tests typically require a long test cycle and moisture intrusion will result in negative test results.

Temperature sensors, such as thermocouples (TCs), or resistance temperature detectors (RTDs), are typically identified by either accessing a connector near the measurement end or applying heat when the TC bead or RTD is accessible and the heat application does not harm the product. Depending on the test configuration, disconnecting and reconnecting can be time consuming and can result in unwanted shorts or open circuits.

Vibration transducers, such as accelerometers, can be identified by removal and attachment of the sensor cable or removal of the transducer and attachment to a small shaker. As with TCs and RTDs, this process can be time consuming and can result in unwanted shorts or open circuits. Moreover, tri-axial sensors cannot typically be identified accurately without disconnecting the cables to each axis.

Likewise, force or pressure transducers typically require disconnecting and reconnecting the attached cables. The application of force or pressure is often not an acceptable option. Most often a shunt resistor is applied to the bridge circuit as an effective identification procedure, but this is also time consuming.

What is needed is a system and method of nondestructive and noninvasive identification of the various cables connected to the various sensors within a multi-channel DAQ system. The cost involved with current methods of identifying the various sensors and cables can be substantial. The costs resulting from damage to sensors and cables and inaccurate data resulting from the identification process can also be considerable.

An object of the present invention, therefore, is to provide a system and method for noninvasive and nondestructive detection of the electrical sensors and cables in a multi-channel DAQ system at a substantially reduced cost.

### SUMMARY OF THE INVENTION

The present invention accomplishes the foregoing objectives by providing a system and method for noninvasive, nondestructive detection of electrical sensors and cables in a multi-channel DAQ system using a specialized probe connected to a FG that induces easily detectable and identifiable signals within each of the multiplicity of sensor cables.

The invention dramatically reduces costs associated with current sensor and cable identification systems. A 1000 channel strain gage project, for example, will require approximately 120 man-hours to complete the identification process. At the common two percent damage rate (20 strain gages at four hours per gage), an additional 80 man-hours are required for repairs, not counting material costs. The invention eliminates these repair costs and reduces identification costs by a factor of six to one. At a $50 per hour labor rate, the total savings is easily $9000 per 1000 strain gage channels. Further savings result from reduced test cycle times and improved fatigue test data.

The present invention provides a probe for nondestructive detection of electrical sensors and cables comprising a slotted, wound toroid carried by a toroid mounting bracket; a blocking capacitor electrically connected on a first end in series with said slotted, wound toroid and carried by a handle mounting block, wherein said handle mounting block is affixed to said toroid mounting bracket; and connection means for electrically connecting the toroid and a second end of said blocking capacitor to a frequency generator.

The present invention further provides a probe for nondestructive detection of electrical sensors and cables in a multi-channel DAQ system comprising a probe comprising a slotted, wound toroid in series with a blocking capacitor having electrical connection means; and a frequency generator in electrical communication with said probe by said electrical connection means.

The present invention also provides a method of noninvasive and nondestructive detection of electrical components and cables in a multi-channel DAQ system, said method comprising the steps of: generating an electrical testing signal using a frequency generator in electrical communication with a probe comprising a slotted, wound toroid in series with a blocking capacitor; placing one or more cables in the slotted portion of said probe; and modulating the frequency of said testing signal to induce a resultant signal in said one or more cables whereby said resultant signal may be observed in said one or more cables for use in identifying electrical components connected to said one or more cables.

The present invention also includes a method of identifying sensors and cables connected to a multi-channel DAQ system said method comprising the steps of: placing a sensor cable disposed within a slotted, wound toroid probe; generating a test signal using a frequency generator whereby said test signal is electrically transmitted from said frequency generator through a connection means to said probe; modulating said test signal to induce a desired resultant signal in said sensor cable; and observing a visual indication of said desired resultant signal to verify connection of said sensor cable to a particular sensor.

### BRIEF DESCRIPTION OF THE DRAWINGS

The invention will be more readily understood with reference to the following specification in conjunction with the drawings herein:

FIG. 1 is an isometric view of a probe and signal generator.

FIG. 2 is a cross-section view of a slotted, wound toroid.

FIG. 3 is a cross-section view of an embodiment of the system in use.

FIG. 4 is a visual depiction of the output of the DAQ system resulting from application of the invention.

FIG. 5 is a visual depiction of the output of the DAQ system resulting from application of the invention.

FIG. 6 is a flow chart indicating the steps involved in performing a method of the invention.

### DESCRIPTION OF THE PREFERRED EMBODIMENTS

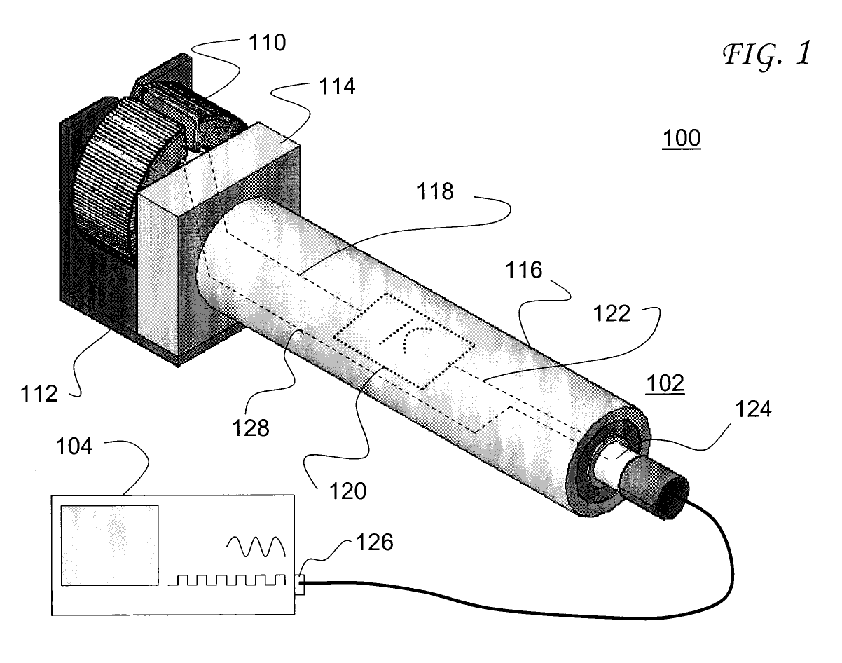

Referring now to FIG. 1, a probe connected to a signal generator is illustrated for providing noninvasive and nondestructive detection of electrical sensors and cables according to a preferred embodiment of the invention. System 100 is comprised of two primary components, probe 102 and signal generator 104.

Probe 102 comprises a wound, slotted toroid 110 mounted within a toroid mounting bracket 112. The toroid mounting bracket 112 is fixed to a handle mounting block 114 that also carries a handle 116 for the probe 102. Electrical conductor 128 connects electrical connector 124 to one of the two wires extending from the wound toroid 110 disposed within bracket 112. The second wire of wound, slotted toroid 110 is connected to a first end of internal capacitor 120 disposed within handle 116 using electrical conductor 118. Electrical conductor 122 connects the second end of capacitor 120 to electrical connector 124 disposed on the end of probe handle 116. In operation, probe 102 is attached to signal generator 104 by electrical connection means so that electrical connector 124 is in communication with frequency generator 104 when input plug 126 is connected to connector 124 using the illustrated cable.

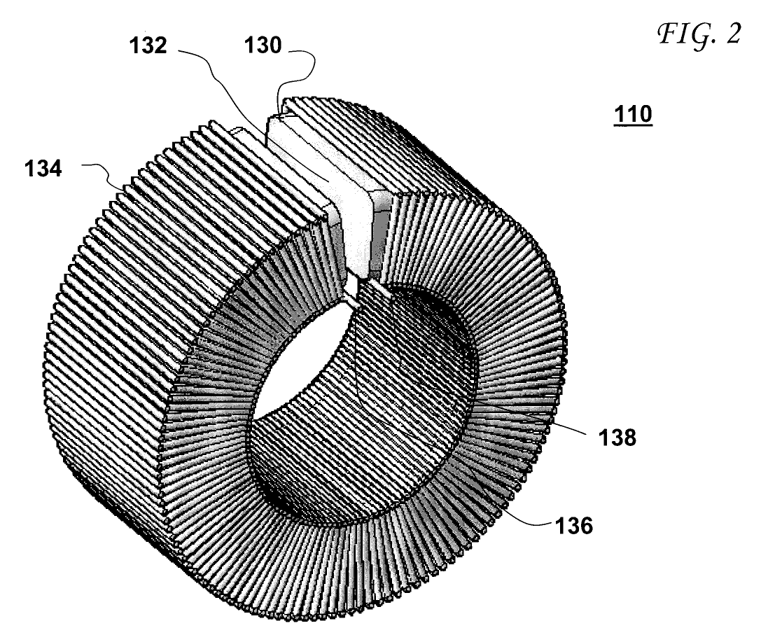

Referring now to FIG. 2, the wound, slotted toroid 110 disposed within probe 102 is illustrated in further detail. Toroid 110 is comprised of a slotted ferrite core 130, including a slot 132, which typically ranges in a preferred width of from 0.2 to 0.35 inches. Ferrite core 130 is surrounded by an insulated wire coil 134 comprised of multiple turns of insulated electrical wire, which is preferably 0.01 inches inner diameter and 0.018 inches outer diameter, although these diameters may vary. Coil 134 terminates into two wire endings, 136 and 138, which are designed to connect to capacitor 120 and connector 124 using conductors 118 and 128 as shown in FIG. 1.

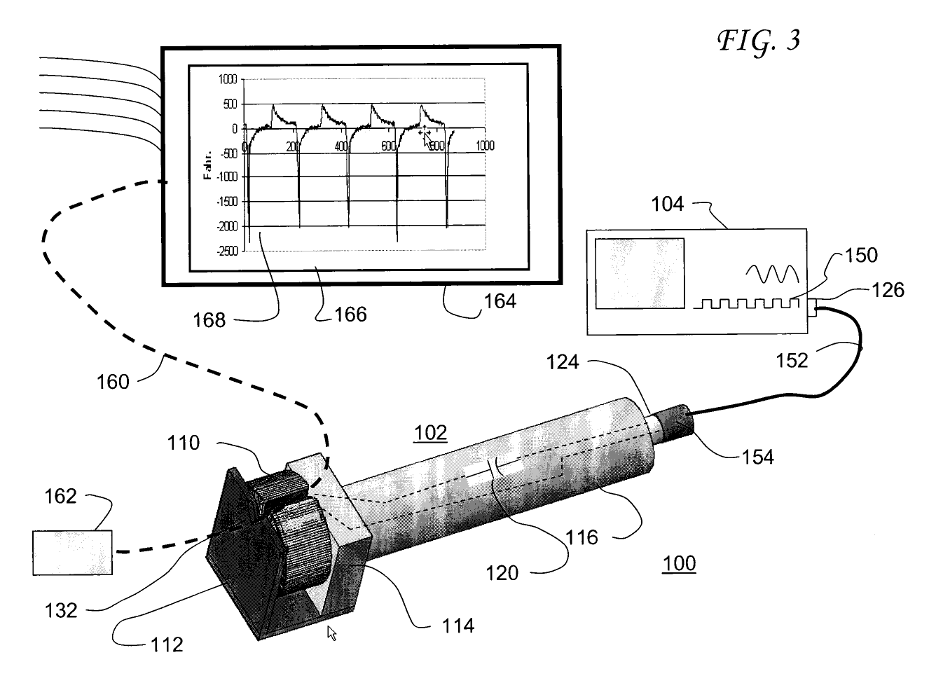

The toroid shape is used in the invention for many reasons. Toroids are relatively small, inexpensive, and can produce a high level of energy internally without radiating externally at a level that might cause false signals to occur on nearby sensor channels. Toroids can also be hand-wired to attain necessary electrical flux fields, frequency response, and current level. A slotted toroid, such as shown in FIG. 2, allows insertion or placement of electrical cables within the slot 132, whereby the signal injected into toroid 110 may be induced into those cables as described more fully in FIG. 3.

Referring now to FIG. 3, system 100 is illustrated as it might be used to identify a typical sensor and cable in a DAQ system. In this embodiment, a technician begins by placing sensor cable 160 into probe slot 132. Signal generator 104 is then used to output an electrical test signal 150 in the form of a ramp, square wave, or sinusoidal wave. Generally test signal 150 is set to a harmonic (arithmetic multiple) frequency of the operating frequency of the DAQ carrier or scanning frequency, plus or minus a small amount as discussed further below. The operating frequency of the DAQ carrier or scanning frequency is also referred to herein as the normal operating frequency of the sensor. Signal 150 flows through cable 152 from signal generator 104 to connector 124 of probe 102. As illustrated, cable 152 uses a corresponding connector 154 that connects to electrical connector 124 disposed on the end of probe 102. Test signal 150 travels through blocking capacitor 120 to toroid 110, whereupon it induces an electromagnetic field of the same harmonic frequency within slot 132. This electromagnetic field then induces test signal 150 into sensor cable 160, which is left in its normal connective state between sensor 162 and DAQ system 164.

Typically, DAQ system 164 includes a built-in oscilloscope 166 housed within a monitor panel of the DAQ system 164. Oscilloscope 166 visually displays the DAQ system response 168 from sensor 162 and cable 160, which indicates the resultant signal. This resultant combined signal results from mixing test signal 150 with the normal operating signal of the DAQ connected to the sensor cable 160. The combined signal is created when probe 102 induces signal 150 into cable 160 via the electromagnetic field within slot 132. In other words, the electromagnetic field contains test signal 150, which is set at a harmonic of the DAQ operating frequency plus or minus a small amount to provide a test signal that is preferred by the operator. Visual signal display 168 is a typical response here where sensor 162 is a thermocouple.

Probe 102 is preferably placed as close to sensor 162 as is reasonably possible. However, probe 102 can be applied at any point along cable 160. The following examples illustrate a method of using the system in greater detail.

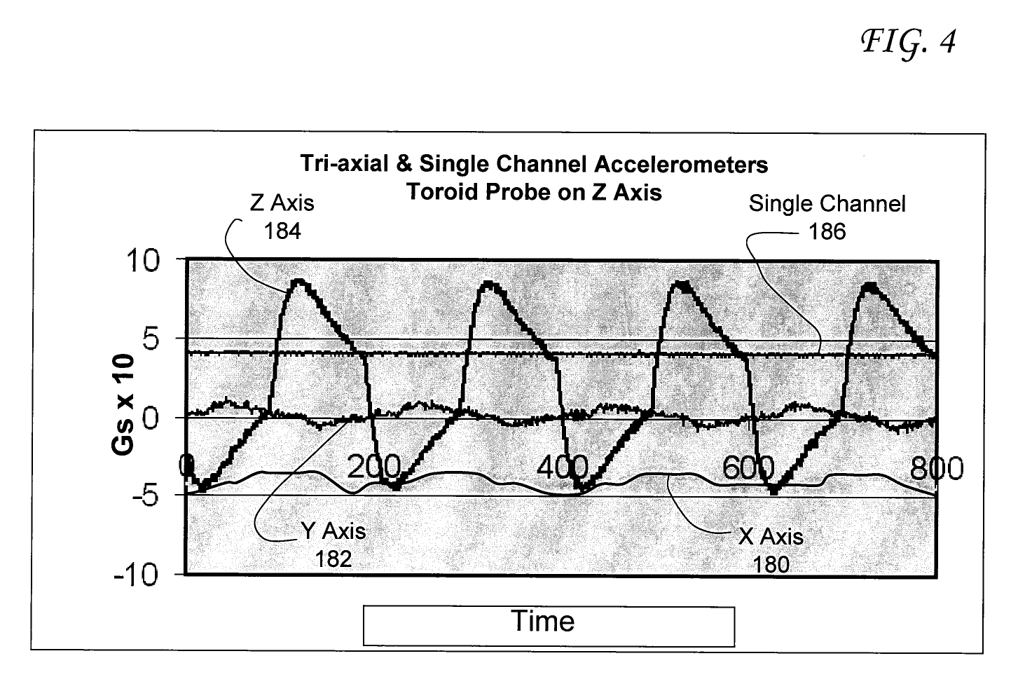

Referring now to FIG. 4, the visual output of a DAQ system oscilloscope, such as oscilloscope 166 on DAQ 164 illustrated in FIG. 3, is set forth using the following parameters. In this example, the probe is applied to the z axis of a tri-axial accelerometer with a uni-axial accelerometer cable in close proximity to the probe. In general terms, the z-axis response is clearly greater than the other channels as indicated by wave form 184. The x and y channel responses, 180 and 182, respectively, show responses that are less than 10% of the z axis response 184. The uni-axial accelerometer response 186 is not affected by its close proximity to the probe as indicated by a virtual straight line without fluctuation. In this way, an operator can clearly and easily identify the z-axis cable of the tri-axial accelerometer without disconnecting the various cables leading to the tri-axial accelerometer.

In more specific terms, this example illustrates a signal generator set to output a test signal that is the 100^{th} harmonic of the DAQ systems operating frequency (a frequency 100 times greater than the DAQ operating frequency). Given a DAQ operating, or scanning, frequency of 150 Hertz, the test signal is set to the 100^{th} harmonic of the DAQ system, which would be 150×100 or 15,000 Hertz, otherwise known as 15 kHz. As discussed above and below, the test signal frequency is then varied by plus or minus a small amount, which amplifies the induction and results in a greater combined signal in the sensor cable.

When the probe is applied to the z-axis, the induced harmonic in the sensor cable on the z axis shows strong acceleration response in Gs as indicated by wave 184. FIG. 4 indicates a clear delineation between the z axis cable and the x and y axis cables, whose output barely registers in wave responses 180 and 182. If the operator were then to attempt identification of the x-axis cable, he need merely remove the z-axis cable and replace it with the x-axis cable in the toroid slot. If performed correctly, the probe would then induce the same combined signal in the x-axis cable so that wave 184 would reduce to the size of wave 180, and wave 180 would enlarge to an output similar to the z axis 184 shown in FIG. 4.

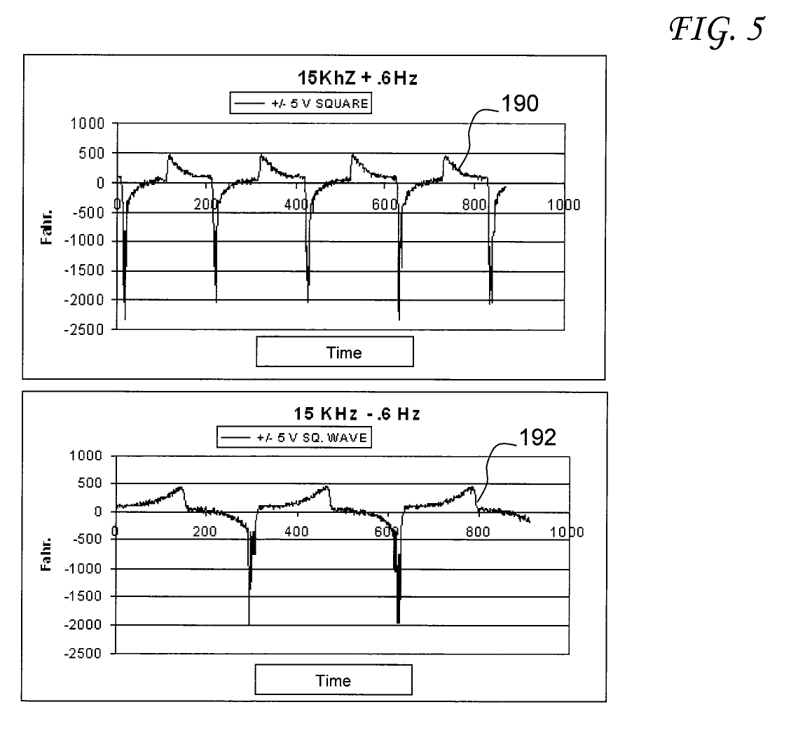

Referring now to FIG. 5, a sample DAQ system response is illustrated using the invention to induce a response upon a thermocouple (temperature) sensor. Here the signal generator is set at the 100^{th} harmonic and the sampling rate of the DAQ system readout is set for 150 samples per second, plus or minus 0.6 Hz. The five-volt square wave test signal induced from the probe operates at a frequency of 100×150 samples per second, which equals 15 kHz. As mentioned above, an exact harmonic of 15 kHz proves less effective and does not produce an acceptable readout on the DAQ system. For that reason, the operator varies the test signal here by plus or minus 0.6 Hz. The resultant combined signal is greatly increased to allow easy identification in the form of a larger amplitude wave as shown in wave readout 190 and 192 in FIG. 5.

Moreover, the shape of the pulse induced into the thermocouple cabling is mirror imaged by the multiple harmonic frequency being slightly plus or minus the exact harmonic, e.g., 0.6 Hz. This illustrates the probe's ability to generate repetitive, complex waveforms but also demonstrates the need for precise frequency control of the FG. An inexpensive FG may provide adequate signal levels for identification but frequency drift of a few Hertz will change the shape of FIG. 4 significantly as the difference in the illustrated waveforms is only 1.2 hertz. Adjustment of the FG to an exact harmonic may produce no response at all as there may be no mixing of the DAQ and probe frequencies. By contrast, an exact harmonic plus or minus a small amount—0.6 Hz in this example—has been shown to induce a very readable response into the sensor cable such that the operator can easily determine sensor identity.

In this manner, the invention is effective for nondestructive and noninvasive detection in identification of virtually any type of sensor and cable because the identification signal is a result of the interference, or mixing, of the measuring system's operating frequency with the harmonic signal frequency superimposed or induced on the sensor wiring. This also necessarily means that the probe can be utilized while the monitored system is operating and the sensors are activated.

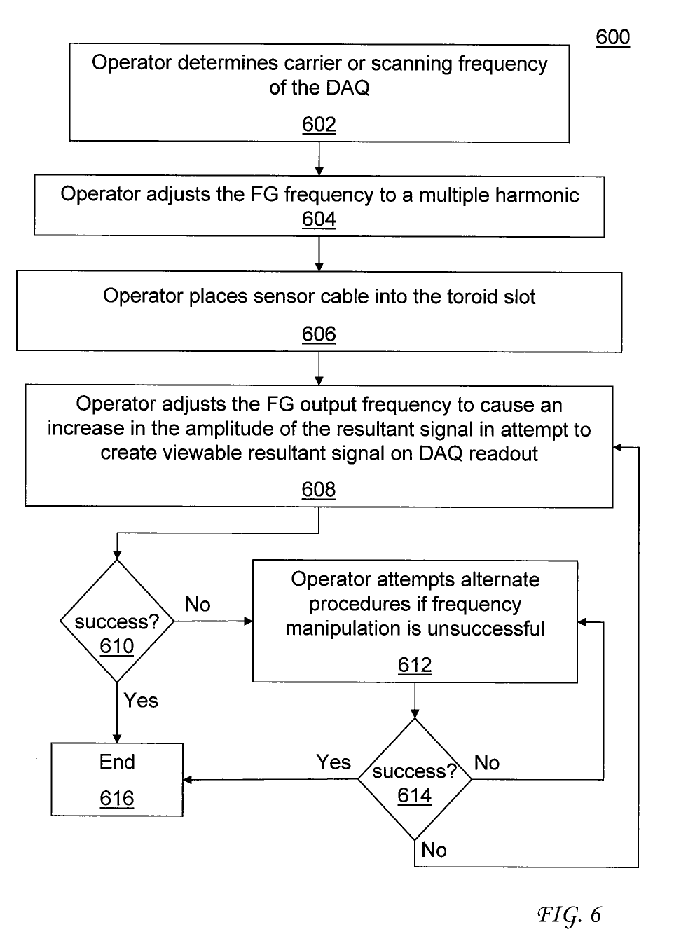

FIG. 6 illustrates the steps 600 involved in a method of one embodiment of using the invention. The operator preferably sets the DAQ to remove all low pass filtering before applying the invention. At step 602, the operator begins by determining the operating frequency of the DAQ.

The operator then selects at 604 an appropriate harmonic frequency of the sensor operating frequency and sets the function generator to output that harmonic frequency. The 3^{rd}, 10^{th}, and 100^{th} harmonics have been shown effective and typically make good starting points. Generally the FG output amplitude should be set at approximately 5 volts peak to peak to avoid overloading the DAQ inputs. As square wave signals are the combination of many frequencies, it is generally easier to obtain a strong signal with the invention using a square wave FG output. If the DAQ system scanning frequency is 100 Hz, for example, the operator may select a harmonic frequency of 100 times that frequency which would equal 100×100 Hz or 10 kHz.

Once the FG is outputting an appropriate harmonic frequency, at step 606 the operator places a sensor cable into the probe slot on the toroid. The probe then induces the harmonic signal into the sensor cable, which combines with the normal operating sensor cable signal already present in the cable. The operator adjusts the FG frequency to cause an amplitude increase in the resultant signal to make it viewable on the DAQ. An exact harmonic often does not produce a strong combined signal, so at step 608 the operator may adjust the FG output frequency slightly higher or lower than the harmonic multiple to increase the amplitude of the resultant combined signal. For example, if no readable combined signal is displayed on the DAQ readout, the operator should begin making small adjustments to the test signal frequency set on the FG. In this example, where the test signal is set at 10 kHz, the operator might choose to lower the FG frequency to 9.999 kHz or raise to 10.001 kHz in step 608. If these adjustments produce the desired readout on the DAQ monitor to allow identification of the sensor and cable, at step 610, the process proceeds to conclusion and ends at step 616.

If mere frequency adjustment in step 608 is not effective, at step 610, the operator makes a decision to proceed to step 612, where he attempts one or more of the following alternate procedures. First, the operator should increase the amplitude of the test signal. If this in ineffective, at step 614, the operator should next change the harmonic integer to change the period of the test signal. Higher harmonics will typically cause a wider pulse width. If that is ineffective, the operator should next change the output to a sinusoidal or ramp output pattern and begin again at step 608. In all cases, proper signal shaping will allow the operator to accurately identify the cables with a hand held digital volt meter if a DAQ monitor panel is not readily accessible. The process continues in this manner until the operator successfully produces a recognizable signal on the DAQ readout and the process ends at step 616.

These illustrated examples are offered by way of illustration of the invention's versatility and not meant to limit the invention in any way. The present invention may be embodied in other specific forms without departing from its spirit or essential characteristics. The blocking capacitor, for example, could be replaced by an electronic circuit that may also provide additional signal features. The described embodiments are to be considered in all respects only illustrative and not restrictive. The scope of the invention is therefore indicated by the appended claims rather than the foregoing description. All changes which come within the meaning and range of the equivalency of the claims are to be embraced within their scope.

1. A probe for nondestructive detection of electrical sensors and cables comprising:
a slotted, wound toroid carried by a toroid mounting bracket;
a blocking capacitor electrically connected on a first end in series with said slotted, wound toroid and carried by a handle mounting block, wherein said handle mounting block is affixed to said toroid mounting bracket; and
connection means for electrically connecting said toroid and a second end of said blocking capacitor to a frequency generator.

2. A system for noninvasive and nondestructive detection of electrical sensors and cables in a multi-channel DAQ system comprising:
a probe comprising a slotted, wound toroid in series with a blocking capacitor having electrical connection means; and
a frequency generator in electrical communication with said probe by said electrical connection means.

3. A method of noninvasive and nondestructive detection of electrical components and cables in a multi-channel DAQ system, said method comprising the steps of:
generating an electrical test signal using a frequency generator in electrical communication with a probe comprising a slotted, wound toroid in series with a blocking capacitor;
placing one or more cables in the slotted portion of said probe; and
modulating the frequency of said testing signal to induce a desired resultant signal in said one or more cables, whereby said resultant signal may be observed in said one or more cables for use in identifying electrical components connected to said one or more cables.

4. The method of claim 3 further comprising the step of increasing the amplitude of said electrical test signal.

5. The method of claim 3 further comprising the step of changing the period of said test signal to a different approximate harmonic frequency.

6. The method of claim 3 further comprising the step of changing the form of said test signal to one of square wave, sinusoidal wave, and ramp wave.

7. A method of identifying sensors and cables connected to a multi-channel DAQ system said method comprising the steps of:
placing a sensor disposed within a slotted, wound toroid probe;
generating a test signal using a frequency generator, whereby said test signal is modulated to an approximate harmonic of the normal operating frequency of said sensor, and whereby said test signal is electrically transmitted from said frequency generator through a connection means to said probe; and
observing a visual indication of said desired resultant signal to verify connection of said sensor cable to a particular sensor.

8. The method of claim 7 further comprising the step of increasing the amplitude of said test signal.

9. The method of claim 7 further comprising the step of changing the period of said test signal to a different approximate harmonic frequency.

10. The method of claim 7 further comprising the step of changing the form of said test signal to one of square wave, sinusoidal wave, and ramp wave.

11. The method of claim 7 further comprising the step of modulating said test signal by small increments to induce a desired resultant signal in said sensor cable
